(19) United States
(12) Patent Application Publication
(10) Pub. No.: US 2019/0155291 A1
(43) Pub. Date: May 23, 2019

(54) METHODS AND SYSTEMS FOR AUTOMATED DRIVING SYSTEM SIMULATION, VALIDATION, AND IMPLEMENTATION

(71) Applicant: Faraday&Future Inc., Gardena, CA (US)

(72) Inventors: Juergen Heit, Mountain View, CA (US); Carlos John Rosario, San Jose, CA (US)

(21) Appl. No.: 15/853,761

(22) Filed: Dec. 23, 2017

Related U.S. Application Data
(60) Provisional application No. 62/438,872, filed on Dec. 23, 2016.
(60) Provisional application No. 62/438,905, filed on Dec. 23, 2016.
(60) Provisional application No. 62/438,913, filed on Dec. 23, 2016.

(51) Int. Cl. G05D 1/02; G05D 1/00; G06F 17/50

(52) U.S. Cl. CPC G05D 1/0221; G05D 2201/0213; G06F 17/5009; G05D 1/0088

(57) ABSTRACT

One or more scenario parameters can be determined. One or more performance metrics can be determined. A vehicle configuration associated with an autonomously operating vehicle can be determined. The autonomously operating vehicle can be simulated in each of one or more scenarios for each of the one or more scenario parameters, each scenario including the determined one or more scenario parameters, wherein at least one of the one or more scenario parameters for each scenario is different from scenario parameters simulated in other scenarios. For each simulated scenario, the one or more performance metrics associated with the simulated scenario can be determined.

### CROSS-REFERENCE TO RELATED APPLICATIONS

This application claims the benefit of U.S. Provisional Application No. 62/438,872, filed Dec. 23, 2016, U.S. Provisional Application No. 62/438,905, filed Dec. 23, 2016, and U.S. Provisional Application No. 62/438,913, filed Dec. 23, 2016, the entireties of which are hereby incorporated by reference.

### FIELD OF THE DISCLOSURE

This relates generally to automated driving and driving assistance systems, and more particularly, to the simulation of autonomous vehicles for quality assurance and safety, for example.

### BACKGROUND OF THE DISCLOSURE

Modern vehicles, especially automobiles, increasingly provide automated driving and driving assistance systems such as blind spot monitors, automatic parking, and automatic navigation. Testing the quality and reliability of an automated vehicle's configuration and driving assistance systems, however, is highly complex and can require prolonged road testing (e.g., billions of hours and miles). The effort required for testing and quality control is multiplied when considering that additional testing may be required after every change to the configuration of an automated vehicle.

### SUMMARY OF THE DISCLOSURE

The various examples of the present invention relate to simulation, validation, and/or testing of an automated vehicle. Specifically, in some examples, an autonomous vehicle can be simulated in a number of different environments (e.g., “scenarios”), environments in which the autonomous vehicle performs most-poorly can be identified (e.g., “minimum performance scenarios”), parameters of the autonomous vehicle (e.g., tire width, sensor locations, etc.) can be varied for those identified minimum performance scenarios to improve the performance of the vehicle in those minimum performance scenarios, and the vehicle having the updated vehicle parameters can be re-simulated to ensure new minimum performance scenarios have not resulted from the changes to the vehicle parameters. In this way, vehicle simulation, validation, testing and/or improvement can be automated.

In various examples described herein, testing may include representing an automated vehicle using a software program configured to simulate real-world environments. In some examples, a representation of an automated vehicle can be derived from inputs extracted from a physical vehicle, such as its dimensions, weight distribution, and other information. In some examples, optimized vehicle configurations may be determined using techniques described herein, and exported to a vehicle. For example, vehicle control systems, optimal vehicle parameters (e.g., sensor positions), and other information can be retrieved from systems described herein to create a safe and reliable autonomous vehicle.

Examples described herein include simulating an autonomous and/or semi-autonomous vehicle in one or more scenarios (e.g., traffic scenarios, weather scenarios, etc.). In some embodiments, scenarios include scenario parameters which can describe the environment of an autonomous vehicle system and can vary incrementally between consecutive scenarios (e.g., scenario parameters can describe objects and their locations in the vehicle's environment, weather conditions in the vehicle's environment, etc.). Vehicle performance can be evaluated, or quality of the autonomous vehicle system can be tested, by determining a performance metric for each scenario (e.g., a quantitative indication of the performance of one or more aspects of the autonomous vehicle, such as the performance of vehicle sensors, the performance of vehicle brakes, etc. in the various scenarios). Vehicle parameters can describe an autonomous vehicle system's configuration, including locations of sensors, vehicle dimensions, automated driving systems included in a vehicle, etc.

Performance metrics below a certain threshold may be defined herein as minimum performance scenarios (e.g., scenarios in which one or more aspects of the autonomous vehicle have minimum performance). Determining minimum performance scenarios in the manners described in this disclosure can reduce the amount of resources required to test an autonomously operating vehicle's reliability by triggering system faults before failures are observed in real-world operation.

### BRIEF DESCRIPTION OF THE DRAWINGS

FIG. 1 illustrates an exemplary system block diagram for simulation and verification of an autonomous vehicle system according to examples of the disclosure.

FIG. 2 illustrates an example process for simulation of an autonomous vehicle system according to examples of the disclosure.

FIG. 3A illustrates an example process for simulating various scenarios of an autonomous vehicle system according to examples of the disclosure.

FIG. 3B illustrates an example graph with scenario parameters mapped to performance metrics according to examples of the disclosure.

FIG. 4A illustrates an example process for improving vehicle parameters in a minimum performance scenario of an autonomous vehicle system according to examples of the disclosure.

FIG. 4B illustrates an example graph with vehicle parameters mapped to performance metrics based on a vehicle analysis according to examples of the disclosure.

FIG. 5 illustrates an exemplary system block diagram of an autonomous vehicle system including automated driving software according to examples of the disclosure.

### DETAILED DESCRIPTION

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples.

Modern vehicles, especially automobiles, increasingly provide automated driving and driving assistance systems such as blind spot monitors, automatic parking, and automatic navigation. Testing the quality and reliability of an automated vehicle's configuration and driving assistance systems, however, is highly complex and can require prolonged road testing (e.g., billions of hours and miles). The effort required for testing and quality control is multiplied when considering that additional testing may be required after every change to the configuration of an automated vehicle.

The various examples of the present invention relate to simulation, validation, and/or testing of an automated vehicle. Specifically, in some examples, an autonomous vehicle can be simulated in a number of different environments (e.g., “scenarios”), environments in which the autonomous vehicle performs most-poorly can be identified (e.g., “minimum performance scenarios”), parameters of the autonomous vehicle (e.g., tire width, sensor locations, etc.) can be varied for those identified minimum performance scenarios to improve the performance of the vehicle in those minimum performance scenarios, and the vehicle having the updated vehicle parameters can be re-simulated to ensure new minimum performance scenarios have not resulted from the changes to the vehicle parameters. In this way, vehicle simulation, validation, testing and/or improvement can be automated.

In various examples described herein, testing may include representing an automated vehicle using a software program configured to simulate real-world environments. In some examples, a representation of an automated vehicle can be derived from inputs extracted from a physical vehicle, such as its dimensions, weight distribution, and other information. In some examples, optimized vehicle configurations may be determined using techniques described herein, and exported to a vehicle. For example, vehicle control systems, optimal vehicle parameters (e.g., sensor positions), and other information can be retrieved from systems described herein to create a safe and reliable autonomous vehicle.

Examples described herein include simulating an autonomous and/or semi-autonomous vehicle in one or more scenarios (e.g., traffic scenarios, weather scenarios, etc.). In some embodiments, scenarios include scenario parameters which can describe the environment of an autonomous vehicle system and can vary incrementally between consecutive scenarios (e.g., scenario parameters can describe objects and their locations in the vehicle's environment, weather conditions in the vehicle's environment, etc.). Vehicle performance can be evaluated, or quality of the autonomous vehicle system can be tested, by determining a performance metric for each scenario (e.g., a quantitative indication of the performance of one or more aspects of the autonomous vehicle, such as the performance of vehicle sensors, the performance of vehicle brakes, etc. in the various scenarios). Vehicle parameters can describe an autonomous vehicle system's configuration, including locations of sensors, vehicle dimensions, automated driving systems included in a vehicle, etc.

Performance metrics below a certain threshold may be defined herein as minimum performance scenarios (e.g., scenarios in which one or more aspects of the autonomous vehicle have minimum performance). Determining minimum performance scenarios in the manners described in this disclosure can reduce the amount of resources required to test an autonomously operating vehicle's reliability by triggering system faults before failures are observed in real-world operation.

In some examples of the disclosure, a learning algorithm can be implemented, such as a neural network (deep or shallow, which may employ a residual learning framework), and can be applied instead of, or in conjunction with, any processes described herein to solve a problem, reduce error, and increase computational efficiency. Such learning algorithms may implement a feedforward neural network (e.g., a convolutional neural network) and/or a recurrent neural network, with supervised learning, unsupervised learning, and/or reinforcement learning. In some examples, backpropagation may be implemented (e.g., by implementing a supervised long short-term memory recurrent neural network or a max-pooling convolutional neural network, which may run on a graphics processing unit). Moreover, in some examples, unsupervised learning methods may be used to improve supervised learning methods. Moreover still, in some examples, resources such as energy and time may be saved by including spiking neurons in a neural network (e.g., neurons in a neural network that do not fire at each propagation cycle).

Additionally, the terms: autonomous driving, autonomous vehicle, autonomously operating vehicle, and/or automated vehicle are used interchangeably to refer to autonomous driving, partially autonomous driving, and/or driver assistance systems. Thus, an autonomous vehicle, as described herein, may refer to a vehicle that is configured to operate in a completely autonomous manner, and may also refer to driver assistance systems on a conventional user-operated vehicle.

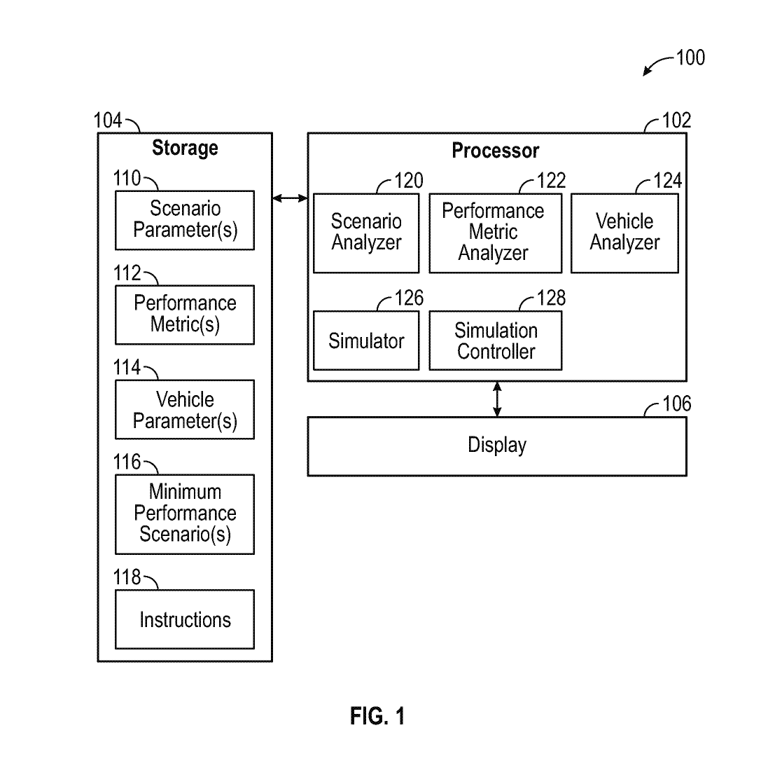

FIG. 1 illustrates an exemplary system block diagram 100 for simulation and verification of an autonomous vehicle system according to examples of the disclosure. System 100 includes processor 102, storage 104 and display 106. As shown in FIG. 1, processor 102 can be coupled to storage 104 to enable the transfer of data between processor 102 and storage 104. Processor 102 can be coupled to display 106 to visually present relevant information. Although FIG. 1 illustrates one processor 102, system 100 can be implemented with one or more computers including one or more processors running a multitude of software processes. In certain examples, each software process can be executed on a different CPU in a computing cluster or mainframe. Alternatively or in addition, some examples may implement processor 102 as hardware, firmware, software, or a combination thereof.

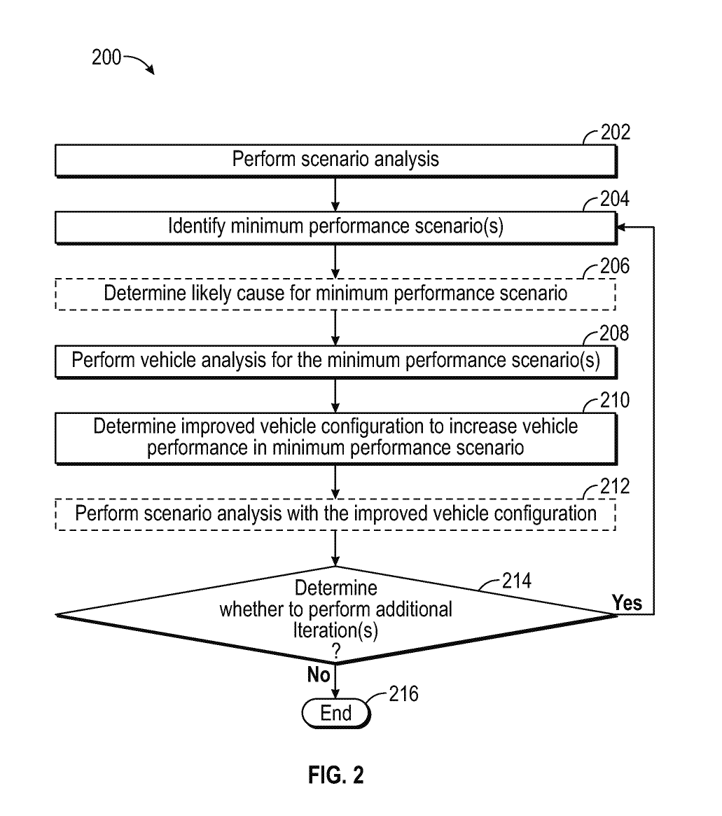

Storage 104 can include one or more non-transitory computer readable storage media, such as a solid-state drive, hard disk drive, a random access memory (RAM), or other possibilities. Storage 104 includes scenario parameter(s) 110, vehicle parameter(s) 114, performance metric(s) 112, minimum performance scenario(s) 116 and instructions 118 of processor 102, which will be described in more detail below and with reference to FIGS. 2-4. In many examples of system 100, scenario parameter(s) 110 describe the various scenarios of the autonomous vehicle system in which the autonomous vehicle system is to be simulated, and processor 102 may change scenario parameters 110 after each scenario is simulated so that the subsequent scenario differs from it incrementally. As a specific example, scenario parameters 110 may describe a scenario in which an autonomous vehicle system attempts to navigate around another vehicle stopped in the road. In one example, scenario parameters 110 may describe the scenario such that the autonomous vehicle system detects the stopped vehicle at a distance of approximately 100 meters, and then attempts to maneuver around the stopped vehicle as soon as it can do so safely. Before simulating the next scenario, processor 102 may incrementally change scenario parameters 110 to describe the next scenario as one in which the autonomous vehicle system detects the stopped vehicle at a distance of approximately 50 meters between the two vehicles, and again attempts to maneuver around the stopped vehicle as soon as it can safely perform the maneuver. Moreover, processor 102 could make additional incremental changes to scenario parameters 110 for subsequent scenarios, so that the distance between the two vehicles continues to decrease with each successive scenario (e.g., to distances of 40 meters, 20 meters and 10 meters, and so on). In this way, the performance of the systems of the autonomous vehicle can be simulated in a number of scenarios.

As another example, scenario parameters 110 may describe a scenario in which the autonomous vehicle system is traveling at 25 miles per hour (MPH) in a school zone and a dog runs into the vehicle's path at a distance of 1.5 meters from the vehicle's front bumper, requiring the autonomous vehicle system to attempt a sudden stop. In one example, processor 102 may change scenario parameters 110 to describe a subsequent scenario with an incrementally increased distance of 1.6 meters between the autonomous vehicle system and the dog when the dog runs in front of the autonomous vehicle. As yet another example, scenario parameters 110 may describe a scenario of the autonomous vehicle system in which the vehicle is traveling at 40 MPH on a busy city road, and a cyclist enters the vehicle's path at a distance of 100 feet and attempts to avoid the vehicle by swerving to the right five seconds later. Scenario parameters 110 may be incrementally changed to describe scenarios with the autonomous vehicle traveling at incrementally increasing speeds when the cyclist enters its path, such as speeds increased to each of 55 MPH, 60 MPH, 65 MPH, and 70 MPH, and with the scenario of each speed of the autonomous vehicle corresponding to scenario parameters 110 describing it. In those examples, the results of the autonomous vehicle's attempts to avoid the cyclist may be evaluated (e.g., processor 102 may determine performance metrics 112 corresponding to the vehicle in each scenario, where such performance metrics can reflect whether the vehicle collided with the cyclist, whether the vehicle caused unsafe driving conditions for other vehicles due to the avoidance maneuver, etc.) for each of the speeds of the autonomous vehicle corresponding to the various scenarios. It is understood that scenario parameters 110 may describe a wide variety of scenarios, and may include one or more of: a distance between the autonomous vehicle system and an object entering its path (e.g., a pedestrian entering the vehicle's path at a distance of 500 meters, 400 meters, 250 meters, 100 meters, or 50 meters, among other possibilities), a type of object present in the scenario (e.g., a cyclist, another vehicle, a pedestrian, an animal, debris, etc.), roads and transportation infrastructure generally (e.g., a winding mountain road, a straight flat road, a four way stoplight intersection, a stop sign intersection, a roundabout, a road under construction, bridges, tunnels, and the like), weather and other environmental data (e.g., precipitation, ambient temperature, humidity, cloud cover, time of day, ambient luminosity or strength of sunlight, wind speed, etc.), traffic conditions (e.g., heavy traffic, light traffic, substantially no other vehicles, large number of pedestrians such as in a crowded parking lot, emergency vehicles driving atypically to arrive at an emergency, among other types of traffic conditions), and events to which the autonomous vehicle system must respond (e.g., a collision between two or more vehicles in the autonomous vehicle system's path, another vehicle suddenly stopping in front of the autonomous vehicle system, another vehicle failing to obey a stop sign or other traffic law, etc.).

In some examples, one or more of scenario parameters 110 may be imported, or may be extracted, from a vehicle database and/or a database of analysis of vehicle accidents or other vehicle scenarios. For example, processor 102 may determine one or more scenario parameters 110 based on data imported into storage 104 from a database of the German In-Depth Accident Study or GIDAS. Further, some examples may import, receive and/or extract one or more of scenario parameters 110 from data reported from real-world vehicles or real-world autonomous vehicle systems. For example, processor 102 may import data from automotive sensors of one or more real-world autonomous vehicle systems. For example, data imported by processor 102 from automotive sensors of one or more autonomous vehicle systems may describe various roads, weather data, and traffic conditions, encountered by those autonomous vehicles, that system 100 can use to determine scenario parameters 110 describing scenarios that include a portion of the imported data.

In some examples, vehicle parameters 114 describe an autonomous vehicle's configuration in a given scenario. In some examples, vehicle parameters 114 may change incrementally between successive scenarios of the autonomous vehicle system, similar to incremental changes of scenario parameters 110 described above. Unlike scenario parameters 110 described above, however, incremental changes in vehicle parameters 114 between scenarios may incrementally change the autonomous vehicle system's configuration rather than the vehicle's surroundings or its environment. As a specific example, vehicle parameters 114 may describe the autonomous vehicle system's weight to be 2,500 pounds in a first scenario in which the autonomous vehicle system must make a sudden stop to avoid a pedestrian entering its path. In one example, vehicle parameters 114 may change before system 100 simulates the next scenario such that the vehicle's weight is 2,750 pounds, but may leave the scenario parameters 110 to describe the rest of the scenario to be the same as the previous scenario (i.e., the autonomous vehicle must attempt to make the same stop in the same amount of time and over the same distance but with an increased vehicle weight). Additionally, vehicle parameters 114 may change before simulating another scenario so that the autonomous vehicle system weighs 3,500 pounds, while the rest of the scenario again remains unchanged, and so on in still later scenarios. In another specific example, scenario parameters 110 may describe a scenario in which the autonomous vehicle system must autonomously maneuver a crowded parking lot, and vehicle parameters 114 may describe the autonomous vehicle system's configuration with a LIDAR sensor positioned 30 centimeters above the top of the autonomous vehicle. For the next scenario with identical scenario parameters 110, processor 102 may incrementally change vehicle parameters 114 so that the autonomous vehicle's LIDAR sensor is positioned four centimeters lower at 26 centimeters above the vehicle's top, and may leave the rest of the scenario unchanged. Further, vehicle parameters 114 may continue to incrementally change after each scenario to describe incrementally decreasing vertical positions of the autonomous vehicle system's LIDAR sensor (e.g., 22 centimeters, 14 centimeters, 8 centimeters), but with identical scenario parameters 110 to describe the scenarios of the crowded parking lot to be identical other than the changes in the autonomous vehicle system's LIDAR positions (or vehicle parameters 114). In this way, the performance of the systems of the autonomous vehicle can be simulated with a number of different vehicle configurations.

It is understood that additional examples of vehicle parameters 114 may include: positions of the vehicle sensors' (e.g., vertical position of a LIDAR sensor relative to the top of the autonomous vehicle, horizontal position of cameras relative to either of the vehicle's sides, forward position of a radar sensor relative to the upper edge of the vehicle's windshield, etc.), configuration of vehicle's sensors (e.g., frequency, wavelength, amplitude, operational bandwidth, etc.), sensor maintenance schedules (e.g., time since sensors were last cleaned, time since sensors were last calibrated, total time sensors have been in operation, etc.), a vehicle weight (e.g., 2,500 pounds, 3,000 pounds, and so on), vehicle center of mass (e.g., distribution of vehicle's weight over its volume), wheel base (e.g., 500 centimeters, 550 centimeters, 600 centimeters, among other possibilities), wheel height, tire width, engine size (e.g., number of cylinders), number and/or configuration of computers controlling an autonomous vehicle system, among other possibilities.

In some examples, performance metrics 112 indicate the quality of the autonomous vehicle system (or its operation), and can be determined for each scenario of the autonomous vehicle system, such as for each scenario simulated during processes 200, 300 and/or 400 as described in greater detail with reference to FIGS. 2, 3 and 4 below). In one example, scenario parameters 110 may describe a scenario in which the autonomous vehicle system is traveling along a freeway at 60 MPH, traffic is stopped 300 meters ahead of the autonomous vehicle which vehicle parameters indicate weighs 3,500 pounds, and the vehicle attempts to automatically stop to avoid colliding with the stopped traffic. In the same example, system 100 may record or determine a performance metric 112 in the scenario that indicates whether (or to what extent) the autonomous vehicle performed the automatic stop while maintaining more than 10 meters between it and the stopped traffic, such that the effectiveness of the vehicle's autonomous driving systems can be evaluated. Performance metrics 112 may be at least partially dependent upon scenario parameters 110 and/or vehicle parameters 114, such that an incremental change in either parameters 110, 114 is likely to produce a change in performance metrics 112. For example, for the scenario with an autonomous stop described previously, subsequent scenarios may include scenario parameters 110 remaining unchanged, while vehicle parameters 114 change the weight of the autonomous vehicle (increase or decrease)—performance metrics 112 may likewise increase and/or decrease in response to such changes depending on the resulting performance of the vehicle. More specifically, vehicle parameters 114 may be changed so the autonomous vehicle's weight increases to 4,000 pounds while the autonomous vehicle attempts the same automatic stop (e.g., according to identical scenario parameters 110 as the previous scenario). After the scenario is completed, the performance metric(s) 112 may indicate that the distance between the autonomous vehicle system and the stopped traffic decreased by 5 meters relative to the distance of the earlier scenario as a result of the increase in the vehicle's weight between the two scenarios. With reference to the same example, the performance metrics 112 of the two scenarios (e.g., the decrease in the distance between the autonomous vehicle system and the stopped traffic after the automatic stop was attempted) may indicate a decrease in the quality of the autonomous vehicle system's automatic braking maneuver between the two scenarios and their respective vehicle parameters 114.

In some examples, performance metrics 112 may be determined in scenarios where vehicle parameters 114 remain unchanged between scenarios (e.g., the vehicle weighs 3,500 pounds in each scenario), but scenario parameters 110 are incrementally changed between each scenario. For example, scenario parameters 110 may be incrementally changed to describe scenarios with distances between the autonomous vehicle system and the stopped traffic that decrease to 250 meters, 200 meters, 100 meters, and so on with each scenario. The performance metrics 112 of the scenarios may indicate corresponding decreases in the quality of the autonomous vehicle's attempt to stop, such as a decrease from over ten meters between the vehicles following the stop in the first scenario to less than 2 meters between the vehicles following the stop in the scenario with a distance of 100 meters. As another specific example, performance metrics 112 may describe a distance between the autonomous vehicle system's LIDAR sensors and an object at which the LIDAR sensors can detect the object, where the object is positioned in front of the autonomous vehicle system, and while the autonomous vehicle system moves at a speed of 65 MPH in heavy rainfall.

It is understood that additional examples of performance metrics 112 may include one or more of: a length of a delay before the autonomous vehicle system senses an object within range of a specified sensor (e.g., delay of 300 milliseconds for the vehicle to detect an object via LIDAR, delay of 800 milliseconds to detect an object via radar, etc.), a braking distance (e.g., requiring 50 meters, 75 meters, 100 meters, etc. to come to a complete stop), a distance between a specified sensor and an object at which the sensor can detect the object (e.g., a LIDAR sensor able to sense an object at distances of 200 meters or less, a radar sensor able to sense an object at distances of 500 meters or less, etc.), a delay between receiving data and engaging one or more vehicle systems to react to the data (e.g., 500 millisecond delay between detecting stopped traffic and engaging the vehicle's brakes, 950 millisecond delay between sensing rainfall and activating windshield wipers, etc.), amount of overcorrection during an autonomous lane keeping maneuver (e.g., correcting vehicle position by 0.5 meters to reenter a lane, correcting vehicle position by 0.2 meters to remain in a lane, etc.), a turning radius of the autonomous vehicle system, Boolean conditions (e.g., whether the autonomous vehicle system has been involved in a collision, whether acceleration exceeded a specified amount, and the like), engine characteristics (e.g., torque during a driving maneuver, fuel consumption, and the like), and/or an acceleration of the autonomous vehicle system, among other possibilities.

In some examples, performance metrics 112 determined in one or more scenarios may indicate that the quality of a maneuver attempted by the autonomous vehicle system in those scenarios was less than a specified quality threshold, and as a result those scenarios may be designated as minimum performance scenarios 116. Further, minimum performance scenarios 116 may be determined to be a subset of the scenarios of the autonomous vehicle system, and may be determined according to an analysis of performance metrics 112 from a variety of scenarios with differing scenario parameters 110. For example, performance metrics 112 may be determined according to a distance from the autonomous vehicle at which the autonomous vehicle can detect a large cargo truck for several scenarios each with varying amounts of snowfall. In some examples, the performance metrics may indicate that scenarios with light snowfall or less resulted in the ability to detect the truck at distances of 100 meters or less, and scenarios with more than light snowfall resulted in a sharp decrease to only being able to detect the truck at distances less than 10 meters. As a specific example, the system 100 may determine that the scenarios with more than light snowfall are minimum performance scenarios 116. As another example, performance metrics 112 may indicate quality of the autonomous vehicle system's sensors based on the autonomous vehicle system's delay to respond to (e.g., brake, maneuver around, etc.) other vehicles in scenarios with differing amounts of vehicle traffic. More specifically, performance metrics may indicate a response delay of 300 milliseconds in scenarios with light traffic, a response delay of 800 milliseconds in scenarios with medium traffic, and a response delay of 500 milliseconds in scenarios with heavy vehicle traffic. In this example, the system 100 may determine that the one or more scenarios with medium traffic and delay times of 800 milliseconds are minimum performance scenarios 116. In some examples, therefore, minimum performance scenarios 116 may be determined based on scenarios with performance metrics 112 that are larger than those of other scenarios, such as where performance metrics 112 measure the autonomous vehicle system's stopping distance or its delays when responding to its surroundings (e.g., in some examples, a high performance metric can indicate undesirable performance, such as long braking distances, or long response delays). Alternatively or in addition, some examples of minimum performance scenarios 116 may be determined based on scenarios with performance metrics 112 that are smaller than those of other scenarios, such as where performance metrics measure the autonomous vehicle system's range for detecting objects via LIDAR, a fuel (or energy) efficiency of the autonomous vehicle system or an acceleration of the autonomous vehicle system (e.g., in some examples, a low performance metric can indicate undesirable performance, such as low energy efficiency, or low acceleration).

In some examples, instructions 118 can include any suitable code (e.g., machine readable) to facilitate operation of processor 102 in conjunction with storage 104 and display 106. In some examples, the instructions 118 may be configured to cause the processor 102 to complete one or more processes described herein (e.g., process 200, 300, and/or 400). In some examples, the instructions 118 may cause the processor 102 to execute one or more modules, programs, or features described herein as part of the processor 102 (e.g., scenario analyzer 120, performance metric analyzer 122, vehicle analyzer 124, etc.) such that the instructions 118 allow the processor to execute the one or more processes described herein.

The processor 102 may include one or more modules, features, and/or programs configured to facilitate (or enable) simulation of an autonomous vehicle system. For example, processor 102 includes a scenario analyzer 120, a performance metric analyzer 122, a vehicle analyzer 124, a simulator 126 and a simulation controller 128. Processor 102 can be configured to perform one or more processes described herein including: a scenario analysis process (e.g., via scenario analyzer 120) to facilitate simulation and analysis of several scenarios of an autonomously operating vehicle, a minimum performance scenario identification process (e.g., via performance metric analyzer 122) to identify any scenarios where performance metrics 112 of one or more scenarios are determined to be less than a specified amount, a vehicle analysis process (e.g., via vehicle analyzer 124) to facilitate simulating several minimum performance scenarios of the autonomous vehicle system and each scenario described by the same scenario parameters 110 and with differing vehicle parameters 114, a vehicle improvement process (e.g., via vehicle analyzer 124) for determining improved vehicle parameters 114 to improve vehicle performance in simulations of a minimum performance scenario, a re-verification process (e.g., via simulator 126 and/or simulation controller 128) to include the improved vehicle parameters 114 in several scenarios and verify whether the improved vehicle parameters 114 result in new minimum performance scenarios 116, and a control process (e.g., via simulation controller 128) to determine whether additional iterations of the processes described above (either individually or any suitable combination thereof) are to be performed. These processes will be described in more detail with reference to FIGS. 2-4. Any or all of the above processes can be performed automatically with minimal or no user input. These processes may include, or be substantially identical to, the processes described in greater detail below.

In some examples, scenario analyzer 120 analyzes performance metrics 112 of various scenarios of the autonomous vehicle system to determine which subset of the scenarios are minimum performance scenarios 116. For example, scenario analyzer 120 may compare performance metrics 112 of several scenarios, and may determine whether one or more performance metrics 112 indicate a quality of operation or of a maneuver attempted by the autonomous vehicle that is less than a specified quality threshold. Moreover, scenario analyzer 120 may operate according to, or may perform, one or more steps of the processes described herein, such that some examples of scenario analyzer 120 may constitute one implementation of process 200 described in greater detail below with reference to FIG. 2.

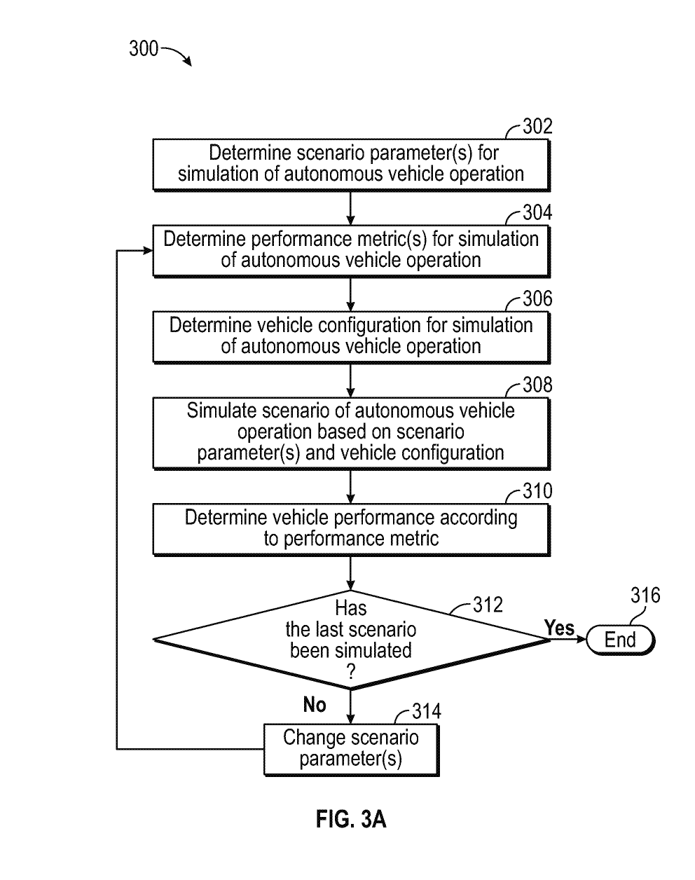

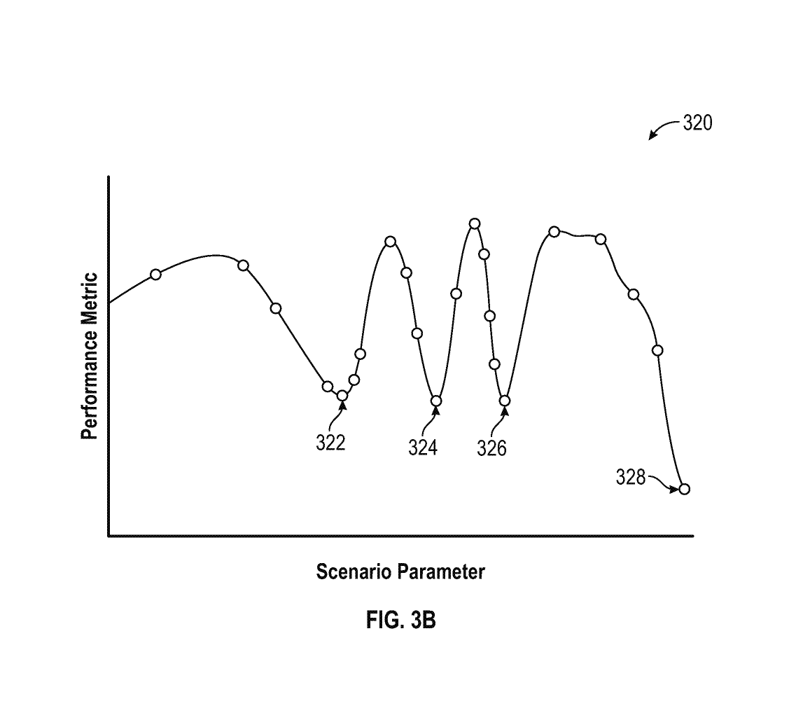

In some examples, performance metric analyzer 122 can determine performance metrics 112 of the scenarios of the autonomous vehicle system. In some examples, performance metric analyzer 122 may determine performance metrics 122 according to user input, such as a user selecting preferred kinds of performance metrics 112 to determine in one or more scenarios by using a keyboard and mouse to select from a list of several types of performance metrics 112. For example, performance metric analyzer 120 may determine performance metrics 112 of one or more scenarios as a turning radius of the autonomous vehicle in response to user input designating turning radius as a performance metric for one or more scenarios. User input could select other kinds of performance metrics, such as, a delay to respond to other vehicles, distance for sensors to detect objects, among others described above. Alternatively, or in addition, performance metric analyzer 122 could automatically determine performance metrics 112 of one or more scenarios, as described above with reference to performance metrics 112 of storage 104. Further, performance metric analyzer 122 may implement one or more steps of process 300, and may determine performance metrics as described with reference to step 310 of FIG. 3A below.

In some examples, vehicle analyzer 124 can determine vehicle parameters 114 of the various scenarios of the autonomous vehicle system. In some examples, vehicle analyzer 124 may determine incremental changes of the vehicle parameters 114 between successive scenarios, as described previously. In some examples, vehicle analyzer 124 may determine vehicle parameters 114 which may determine the autonomous vehicle system's configuration in the first scenario of the autonomously vehicle system. For example, vehicle analyzer 124 may determine the vehicle parameters 114 of the first simulation such that the autonomous vehicle system weighs approximately 2,750 pounds, is equipped with LIDAR sensors, radar sensors, cameras and other sensors, and may determine a make, a model and the corresponding features of the autonomous vehicle system.

In some examples, simulator 126 and simulation controller 128 may simulate the various scenarios according to scenario parameters 110 and vehicle parameters 114 as determined by scenario analyzer 120 and vehicle analyzer 124. The simulator 126 may utilize contents of storage 104 (e.g., scenario and vehicle parameters 110, 114, performance metrics 112, minimum performance scenarios 116 and/or instructions 118) to simulate the autonomous vehicle system and its environment (e.g., other vehicles, pedestrians, cyclists, the weather, and other scenario parameters 110 as described above) to behave in a manner that is substantially identical to their real-world counterparts. Certain examples of system 100 may present a simulation performed by simulator 126 in a visual format on display 106. Alternatively or in addition, some examples of system 100 may record information associated with a simulation performed by simulator 126 in storage 104. For example, simulator 126 may store scenario and vehicle parameters 110, 114, performance metrics 112 and other data, in storage 104 following each scenario of the autonomous vehicle system.

Simulator 126 and simulation controller 128 may operate to perform any control logic of systems 100, 500 or processes 200, 300 and 400 as described herein. For example, the simulation controller 128 may determine whether to perform additional iterations of process 200 at step 214 of that process, as described in greater detail below with reference to FIG. 2.

FIG. 2 illustrates an example process 200 for simulation of an autonomous vehicle system according to examples of the disclosure. Some examples of process 200 may be performed by system 100. Alternatively or in addition, some examples of process 200 may be performed by the autonomous vehicle system 500, a server and/or a cloud computing system. As a general example, system 100 may perform process 200 by simulating several scenarios of the autonomous vehicle system and incrementally varying scenario parameters 110 between successive scenarios, determining performance metrics 112 of the various scenarios, determining minimum performance scenarios 116 as a subset of the scenarios, and improving vehicle parameters 114 by comparing performance metrics 112 determined from several scenarios with identical scenario parameters 110 and incrementally varying vehicle parameters 114 to optimize vehicle parameters and performance, as will be described in more detail below.

At 202, system 100 can perform a scenario analysis by simulating several scenarios, and determining performance metrics 112 of the scenarios. In one example, as part of step 202, system 100 may simulate a variety of scenarios of the autonomous vehicle system, with vehicle parameters 114 of each simulation being identical, and the scenario parameters 110 describing each scenario changing incrementally with each subsequent scenario, as described with reference to scenario parameters 110 of FIG. 1. System 100 may determine performance metrics 112 of the scenarios as described in greater detail above with reference to performance metrics 112 of FIG. 1. Scenario analysis, and step 202 generally, are described in greater detail below as process 300 with reference to FIG. 3A (i.e., process 300 outlines one example of step 202 in greater detail).

At 204, system 100 may identify one or more minimum performance scenarios 116, as described in greater detail above with reference to FIG. 1. System 100 may determine an average quality of the autonomous vehicle systems of the scenarios as indicated by the performance metrics 112. For example, system 100 could determine performance metrics 112 of the scenarios as a braking distance, and may determine an average braking distance (distance required for the autonomous vehicle system to slow to a stop) for a speed of 65 MPH in several scenarios to be 30 meters and a standard deviation in braking distance to be 5 meters. In this example, system 100 may determine minimum performance scenarios 116 as scenarios with performance metrics 112 indicating a braking distance greater than the average of 30 meters by a standard deviation (5 meters) or more. Alternatively or in addition, system 100 could determine minimum performance scenarios to be scenarios with braking distances exceeding the average of 30 meters by two standard deviations or more (10 meters), among other possible methods for determining minimum performance scenarios 116.

In certain examples, process 200 may include step 206, so that system 100 determines a likely cause for one or more of the minimum performance scenarios 116 of step 204. For example, if luminosity of shining sunlight is a scenario parameter 110 of a minimum performance scenario 116, then system 100 may determine that a likely cause of the minimum performance scenarios 116 is overexposure of one or more of the autonomous vehicle's sensors. In some examples, a likely cause of one or more minimum performance scenario 116 may be determined based on one or more predetermined threshold values of the various scenario parameters. For example, failing to detect an object appearing less than one foot before a simulated vehicle may be attributed to known minimum sensing distance as a likely cause of the minimum performance scenario 116. Alternatively, some examples of process 200 may omit step 206, and may perform step 208 without identifying a likely cause of a minimum performance scenario.

At 208, system 100 may perform a vehicle analysis, and may simulate several configurations of the autonomous vehicle system in the minimum performance scenario(s) 116 determined at 204 by incrementally changing vehicle parameters 114. As described in greater detail above with reference to vehicle parameters 114 of FIG. 1, vehicle parameters 114 can define the configuration of the autonomous vehicle system of a scenario, such as the vehicle's sensor configuration, make, model, tires and/or vehicle mileage, among other possibilities. In many examples, system 100 may determine performance metrics 112 of the minimum performance scenario(s) as it varies vehicle parameters 114 to determine whether changing vehicle parameters 114 results in any changes in the performance metrics 112 (e.g., improvements of the performance metrics in those scenarios). Additionally, system 100 may determine performance metrics 112 for each of the variety of scenarios with unique vehicle parameters 114. In certain examples, system 100 may improve the vehicle parameters 114, or determine improved vehicle parameters 114, based on the performance metrics 112 of the scenarios having incrementally varying vehicle parameters 114 at step 210. For example, if given changes in vehicle parameters cause improvements in the performance metrics 112 of interest, system 100 can identify those vehicle parameters as improved vehicle parameters associated with the minimum performance scenario(s).

In certain examples, process 200 may include step 212, so that system 100 performs a scenario analysis, as described for step 202 above, but with the improved vehicle parameters 114 of step 210, rather than the initial vehicle parameters of step 202. In many examples, system 100 may perform step 212 by testing, verifying, and/or confirming whether an improved vehicle configuration from step 210 results in any new minimum performance scenarios 116. For example, improved vehicle parameters 114 may include a wider tire base, and system 100 may determine performance metrics 112 for the wider tire base (i.e., the improved vehicle parameters) to determine whether unexpected minimum performance scenarios 116 exist, such as a sharp decrease in fuel economy of the autonomous vehicle system. In some examples, system 100 may test the improved vehicle parameters across multiple scenarios (e.g., as described with reference to step 202) to identify minimum performance scenarios (if any) associated with the improved vehicle parameters.

At 214, system 100 may determine whether to perform an additional iteration of process 200 beginning at step 204. System 100 may determine whether to perform an additional iteration of process 200 based on criteria from a user or determined by 100. As a specific example, a user or system 100 may specify a number of iterations of process 200 for system 100 to perform before forgoing additional iterations of process 200 at step 214. As another specific example, system 100 may determine whether to end process 200 based on a confidence index of the results of steps 204, 206, and 208, where the confidence index indicates a statistical reliability of the results of steps 204, 206 and 208. Additional examples of criteria for determining whether to forgo additional iterations of process 200 may include: whether a previously specified number of iterations of process 200 has occurred, whether vehicle parameters 114 were substantially improved, whether improved vehicle parameters 114 resulted in unexpected minimum performance scenarios 116, among other possibilities. In some examples, system 100 may determine to forgo performing an additional iteration of process 200, and system 100 may perform step 216 by ending process 200.

FIG. 3A illustrates an example process 300 for simulating various scenarios of the autonomous vehicle system according to examples of the disclosure. As a general description, process 300 may include simulating scenarios of the autonomous vehicle system, and incrementally changing scenario parameters 110 between each scenario. As mentioned previously, process 300 is a more detailed description of scenario analysis at step 202 of FIG. 2 according to a variety of examples described herein. Additionally, the following description of process 300 may provide a more complete description of features (or steps) mentioned above with reference to process 200 of FIG. 2.

At 302, the system may determine scenario parameters 110 to describe the scenario of the autonomous vehicle system, as described in greater detail above, with reference to FIG. 1. According to the more detailed description of scenario parameters 110 of FIG. 1, scenario parameters 110 describe the various scenarios of the autonomously operating vehicle, such as the environment and surroundings of the autonomous vehicle system.

As a single specific example, scenario parameters 110 may describe a scenario in which a cyclist enters the path of the autonomously operating vehicle while it travels at a speed of 45 MPH and with a distance of 100 meters between the cyclist and the autonomous vehicle system. The scenario parameters 110 may change incrementally, as will be described below, to describe subsequent scenarios with decreasing distances between the cyclist and the autonomous vehicle system. For example, scenario parameters 110 may vary to describe subsequent scenarios with distances of 50 meters, 20 meters, 15 meters, 12 meters, among other possibilities, between the cyclist and the autonomous vehicle system. In some examples, scenario parameters 110 may be determined based on past iterations of process 300, such as where previous scenarios indicate a high probability of minimum performance scenarios 116 for particular scenario parameters 110. For example, during a first iteration of process 300, system 100 may determine minimum performance scenarios 116 as scenarios with more than light snow fall, and may determine scenario parameters 110 in later iterations of process 300 based on scenario parameters 110 of the previously determined minimum performance scenarios 116 (i.e., the system may focus its simulations on those scenarios with medium or greater snowfall).

At 306, system 100 may determine vehicle parameters 114 to describe the autonomous vehicle system's configuration, as described in greater detail above with reference to FIG. 1. In some examples, system 100 determines vehicle parameters 114 for a first scenario of process 300 and holds vehicle parameters constant for all following scenarios simulated during later iterations of the process 300 performed without interruption (e.g., without performing step 316 which ends process 300). For example, system 100 may determine vehicle parameters 114 to describe a specific configuration of the autonomous vehicle system for scenarios in which the autonomous vehicle system must navigate a turn at increasing speeds, and the vehicle parameters 114 may remain fixed for each of several scenarios with vehicle speeds such as 25 MPH, 40 MPH, 50 MPH, 65 MPH, etc.

At 308, system 100 simulates a scenario of the autonomous vehicle system, according to scenario parameters 110 and vehicle parameters 114, as described in greater detail above with reference to FIG. 1. Also as described in greater detail above with reference to FIG. 1, one or more processors, servers or simulation systems may perform the simulation.

At 310, system 100 determines vehicle performance metrics 112 of the scenario simulated at step 308. As explained in greater detail above with reference to FIG. 1, performance metrics 112 determined at step 310 may indicate the quality of the autonomous vehicle system or of a driving maneuver attempted by the autonomous vehicle system and/or a driver of the autonomous vehicle system (e.g., an automatic braking maneuver, autonomous lane change, driver assisted cruise control, among other possibilities). Moreover, and also described above with reference to FIG. 1, some examples of performance metrics 112 may include one or more of: a length of a delay before the autonomous vehicle system senses an object within range of a specified sensor (e.g., delay of 300 milliseconds for the vehicle to detect an object via LIDAR, delay of 800 milliseconds to detect an object via radar, etc.), a braking distance (e.g., requiring 50 meters, 75 meters, 100 meters, etc. to come to a complete stop), a distance between a specified sensor and an object at which the sensor can detect the object (e.g., a LIDAR sensor able to sense an object at distances of 200 meters or less, a radar sensor able to sense an object at distances of 500 meters or less, etc.), a delay between receiving data and engaging one or more vehicle systems to react to the data(e.g., 500 millisecond delay between detecting stopped traffic and engaging the vehicle's brakes, 950 millisecond delay between sensing rainfall and activating windshield wipers, etc.), amount of overcorrection during an autonomous lane keeping maneuver (e.g., correcting vehicle position by 0.5 meters to reenter a lane, correcting vehicle position by 1.5 meters to remain in a lane, etc.), a turning radius of the autonomous vehicle system, Boolean conditions (e.g., whether the autonomous vehicle system has been involved in a collision, whether acceleration exceeded a specified amount, and the like), engine characteristics (e.g., torque during a driving maneuver, fuel consumption, and the like) and/or an acceleration of the autonomous vehicle system, among other possibilities.

At 312, system 100 determines whether to simulate additional scenarios of the autonomous driving system (e.g., system 100 determines whether the last scenario of process 300 has been simulated). In some examples, the last scenario may be simulated once a sufficient number of minimum performance scenarios 116 have been identified as a percentage of all scenarios. For example, the last scenario may be simulated once three scenarios are determined to be minimum performance scenarios 116 from a total of at least 30 scenarios. Alternatively, or in addition, in some examples the last scenario may be simulated only after simulating a specified number of scenarios and only after simulating scenarios with specified scenario parameters 110. For example, system 100 may forgo simulating further scenarios of the autonomous vehicle system navigating various amounts of traffic in response to determining that thirty scenarios have been simulated, and that scenarios with the little or no vehicle traffic, and scenarios with very congested traffic have both been simulated.

At 314, system 100 changes scenario parameters 110 to use in simulating the next scenario of the autonomous vehicle system at step 308, and begins an additional iteration of process 300. In certain examples, the amount of change in scenario parameters 110 between consecutive scenarios may be a constant or fixed amount of change for a portion of changes in scenario parameters 110 between the scenarios of process 300. For example, in simulating several scenarios in which the autonomous vehicle system travels down an incline, the grade of the incline may be increased by 1 degree after some portion of the scenarios (e.g., change a 10 degree incline of one scenario to an 11 degree incline in the following scenario then to a 12 degree incline in the third scenario, and so on). Alternatively or in addition, some examples may include dynamically determining one or more changes in scenario parameters 110 between consecutive scenarios of the autonomous vehicle system. In some examples, a change in scenario parameters 110 may be proportional to one or more changes in performance metrics 112. For example, a scenario in which autonomous vehicle speed is 45 MPH may correspond with a stopping distance of 60 meters, a subsequent scenario with a vehicle speed of 55 MPH may correspond with a stopping distance of 75 meters, and the autonomous vehicle's speed in a third scenario (i.e., the scenario parameters of the third scenario) may be changed to 58 MPH based on the increase in stopping distance of 15 meters resulting from the first change in scenario parameters (e.g., system 100 may only increase the vehicle speed by 3 MPH, rather than 10 MPH, due to the relatively large increase in the stopping distance when the vehicle speed increased from 45 MPH to 55 MPH). Some examples may determine step size of, or the amount of change in, scenario parameters 110 based on a slope of performance metrics 112, when performance metrics 112 are graphed as a function of scenario parameters 110, as illustrated below in FIG. 3B.

In some examples, system 100 may determine step size in scenario parameters 110 based on whether changes in performance metrics 112 of the previous scenario exceeded specified threshold amounts. For example, the threshold amount of change in performance metrics 112 may be an average change in performance metrics 112 previously determined from several implementations of process 300. Moreover, the amount of change in scenario parameters 110 may decrease for an amount of change in performance metrics 112 that exceeds the threshold (or average) amount, and where the amount of change in performance metrics 112 is less than the threshold amount, the amount of change in scenario parameters 110 may increase. Alternatively or in addition, some examples of process 300 may include determining changes in scenario parameters 110 according to one or more statistical methods. For example, system 100 may simulate a fixed number of scenarios of the autonomous vehicle system automatically braking while traveling down an incline, and may randomly determine the incline of each scenario according to a normal (e.g., Gaussian) distribution of the degree of incline (i.e., of the scenario parameters 110) with the distribution centered at 15 degrees. More generally, system 100 may use one or more of machine learning, deep learning and/or neural networks to change scenario parameters at step 314. For example, one or more machine learning algorithms may be used to determine what change in scenario parameter is most likely to facilitate identifying a minimum performance scenario in fewest iterations of process 300.

At 316, system 100 completes process 300 after determining to forgo additional scenarios of the autonomous vehicle. In some examples, system 100 may record any scenario parameters 110, performance metrics 112, vehicle parameters 114 and/or minimum performance scenarios 116, and any other relevant data, in storage 104 before process 300 is terminated.

FIG. 3B illustrates an example graph 320 with scenario parameters mapped to performance metrics according to examples of the disclosure. As described above with reference to FIG. 1, scenario parameters may vary between consecutive scenarios of the autonomous vehicle system, such that simulating several scenarios of the autonomous vehicle system may result in a wide variety of scenario parameters describing those scenarios. Moreover and as also described with reference to FIG. 1, system 100 may determine performance metrics from the scenarios, such that each scenario includes scenario parameters and a corresponding performance metric determined from that scenario. In some examples, therefore, performance metrics may be mapped as a function of scenario parameters (or scenario parameters may be mapped to performance metrics) with a single set of vehicle parameters that are identical in each of the scenarios of the scenario parameters and performance metrics.

Graph 320 illustrates several points 322, 324, and 326 that system 100 may correspond to scenario parameters and performance metrics of three minimum performance scenarios 116, as described in greater detail above with reference to FIG. 1 (e.g., points 322, 324 and 326 can correspond to scenarios in which the current vehicle configuration performance most poorly according to the current performance metric). In some examples, point 328 illustrates a scenario in which scenario parameters were outside of a known operational range of the autonomous vehicle system, and as a result may be disregarded. For example, point 328 may illustrate a scenario in which a cyclist moved into the path of the autonomous vehicle system with a distance of two feet between the cyclist and the autonomous vehicle and while the autonomous vehicle system was traveling at a speed of 45 MPH. More specifically, in such an example, point 328 may be disregarded as a result of system 100 determining that no vehicle parameters are likely to produce any improvement in the performance metrics of the scenario represented by point 328.

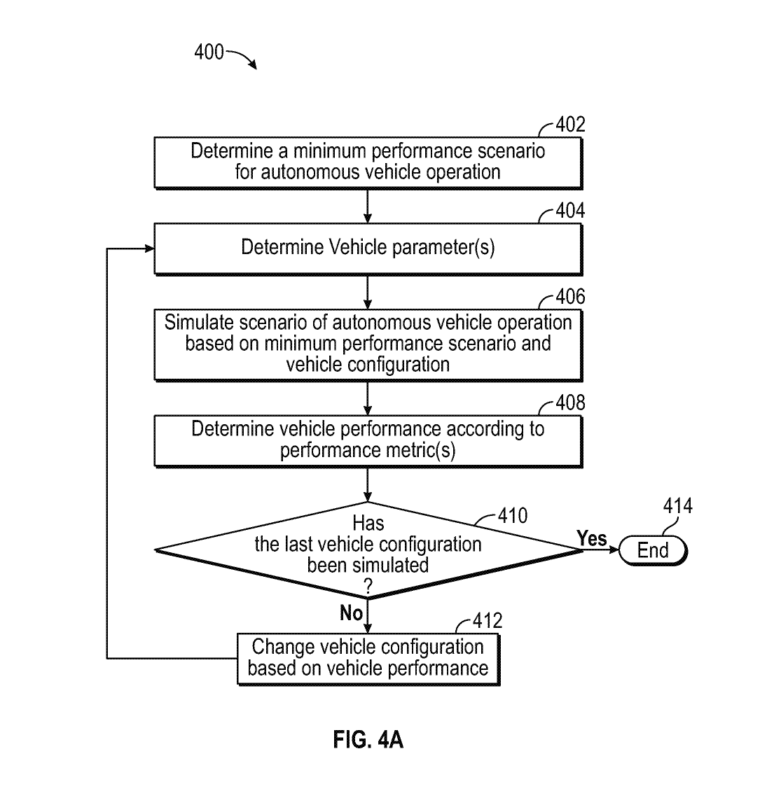

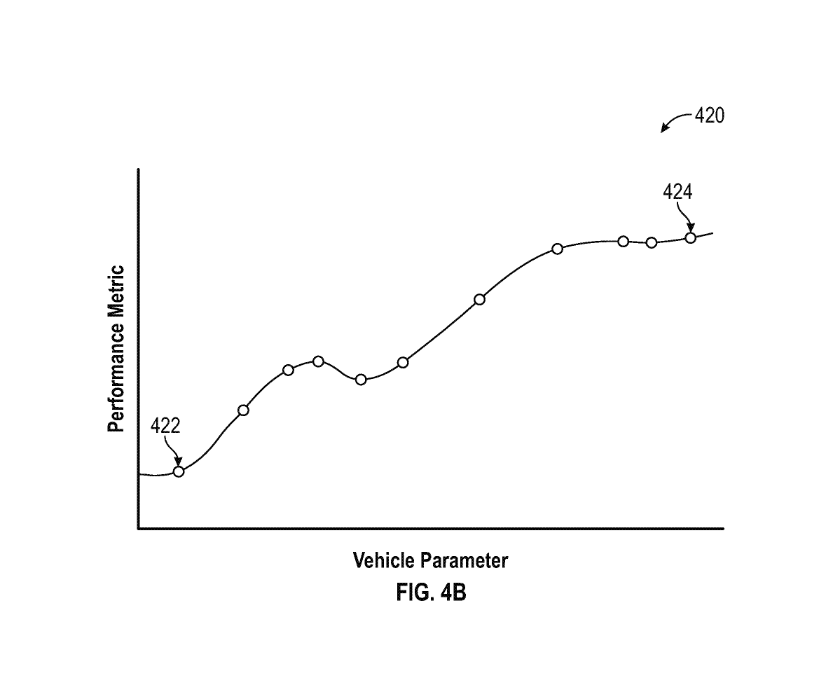

FIG. 4A illustrates an example process 400 for improving vehicle parameters in a minimum performance scenario of the autonomous vehicle system according to examples of the disclosure. In many examples, process 400 may improve vehicle parameters in a minimum performance scenario based on several simulations of the minimum performance scenario, each with varying vehicle parameters. Process 400 is a more detailed description of a vehicle analysis, or step 208 of FIG. 2, according to several examples disclosed herein.

At 402, a minimum performance scenario is determined, or the scenario parameters of a minimum performance scenario are identified to use in the scenarios simulated during process 400. For example, system 100 may determine the minimum performance scenario (according to the description of a minimum performance scenario given in greater detail with reference to FIG. 1) by retrieving it from storage 104, where the minimum performance scenario was stored during previous iteration(s) of process 300.

At 404, vehicle parameters to describe the autonomous vehicle system in the first scenario of process 400 are determined. In some examples, vehicle parameters may be determined to be identical to vehicle parameters of a previously completed scenario analysis (i.e., a previous implementation of process 300) so the autonomous vehicle system of the first scenario of process 400 includes the vehicle parameters with which the minimum performance scenario of step 402 was first identified. In some examples, vehicle parameters may be determined based on an aspect of the autonomous vehicle system's configuration determined by system 100 to likely be a substantial factor in the minimum performance scenario. As described in greater detail above with reference to FIG. 1, vehicle parameters may describe the autonomous vehicle system's configuration, and may vary between scenarios. Some examples of vehicle parameters 114 may include one or more of: positioning of the autonomous vehicle system's sensors (e.g., vertical position of LIDAR sensor relative to the vehicle's top, horizontal position of cameras relative to either of the vehicle's sides, forward position of radar sensor relative to the upper edge of the vehicle's windshield, etc.), configuration of vehicle's sensors (e.g., frequency, wavelength, amplitude, operational bandwidth, etc.), sensor maintenance schedules (e.g., time since sensors were last cleaned, time since sensors were last calibrated, total time sensors have been in operation, etc.), vehicle weight (e.g., 2,500 pounds, 3,000 pounds, etc.), vehicle center of mass (e.g., distribution of vehicle's weight over its volume), wheel base, wheel height, engine size, number and/or configurations of computers controlling a vehicle (e.g., algorithms used to control the autonomous vehicle system), among other possibilities.

At 406, the minimum performance scenario determined at step 402 (or a scenario described by scenario parameters of a minimum performance scenario determined at step 402) is simulated with the vehicle parameters determined at step 404, according to scenarios as described in greater detail above with reference to FIG. 1.

At 408, one or more performance metrics of the scenario of step 406 are determined, according to the description of performance metrics given above with reference to FIG. 1. In some examples, vehicle parameters may be mapped to corresponding performance metrics to create a curve or graph relating vehicle parameters and performance metrics for the given set of scenario parameters (e.g., as illustrated by graph 420 in FIG. 4B).

At 410, whether to simulate an additional scenario of the autonomous vehicle system with a different set of vehicle parameters and in the minimum performance scenario is determined. In some examples, simulating another scenario of the autonomous vehicle with different vehicle parameters may be forgone in response to sufficient improvement of the vehicle parameters of the minimum performance scenario (i.e., sufficient increase in performance metrics determined in scenarios of the autonomous vehicle system using the vehicle parameters). For example, additional simulations of vehicle parameters in a minimum performance scenario measuring braking distance may be forgone once vehicle parameters result in a stopping distance less than one hundred feet for a speed of 60 MPH. Alternatively, or in addition, some examples may determine step 410 based on whether a specified number of scenarios with different vehicle parameters have been simulated and whether specific vehicle parameters have been included in the scenarios of the autonomous vehicle system. For example, system 100 may forgo simulating further scenarios of the autonomous vehicle system navigating medium traffic once thirty scenarios with different vehicle parameters have been simulated, and once scenarios with vehicle parameters positioning the autonomous vehicle's LIDAR sensor at vertical positions of 10 centimeters and 30 centimeters have both been simulated.

At 412, vehicle parameters are changed to be used in the next scenario of the autonomous vehicle system and an additional iteration of process 400 begins. In certain examples, changes in vehicle parameters may be constant or fixed for a portion of all changes of vehicle parameters between scenarios of process 400. For example, after one or more scenarios in which the autonomous vehicle system travels down an incline have been simulated, the wheelbase of the autonomous vehicle system may be increased by 10 centimeters (e.g., change the wheelbase from 500 centimeters in one scenario to 510 centimeters in the following scenario and then to 520 centimeters in a third scenario, and so on). Alternatively or in addition, some examples may include dynamically determining one or more changes in vehicle parameters between consecutive scenarios of the autonomous vehicle system in the minimum performance scenario of step 402. In some examples, a change in vehicle parameters may be proportional to one or more changes in performance metrics determined in scenarios simulated during process 400. For example, a scenario in which the tire width of the autonomous vehicle system is 200 millimeters and its speed is 60 MPH may correspond with a stopping distance of 110 feet, a subsequent scenario with the same vehicle speed of 60 MPH but an increased tired width of 210 millimeters may correspond with a stopping distance of 105 feet, and the tire width of the autonomous vehicle system in a third scenario (i.e., the vehicle parameters of the third scenario) may be changed to 215 millimeters based on the decrease in stopping distance of five feet that resulted from the first change in the vehicle parameters (e.g., system 100 may only increase the tire width by 5 millimeters, rather than 10 millimeters, due to the relatively large decrease in the stopping distance when the tire width increased from 200 millimeters to 210 millimeters).

Some examples may determine step size of, or the amount of change in, vehicle parameters based on a slope of the performance metrics 112 determined during process 400, such as a slope between two points of performance metrics 112 graphed as a function of vehicle parameters 110 in FIG. 4B. As an example, system 100 may determine step size in vehicle parameters 114 between two scenarios during process 400 based on whether the amount of change in the performance metrics 112 of previous scenarios during process 400 exceeded a specified threshold amount. For example, the threshold amount of change in the performance metrics 112 of scenarios during process 400 may be an average amount of change in the performance metrics 112 of the scenarios simulated during process 400 up to that point, or as determined from several previous implementations of process 400. As a specific example, performance metrics 112 of scenarios during process 400 could include delays of 500 milliseconds, 505 milliseconds, 506 milliseconds, and 510 milliseconds for various vehicle parameters of previous scenarios simulated during process 400. In the same example, an average amount of change in performance metrics 112 (e.g., to be used as a threshold amount of change) can be determined to be 3.34 milliseconds as the average amount of change in delay time between the previously simulated scenarios. Moreover, the amount of change in vehicle parameters 114 between scenarios may decrease for an amount of change in performance metrics 112 that exceeds the threshold (or average) amount, and where the amount of change in performance metrics 112 is less than the threshold amount the amount of change in vehicle parameters 114 between scenarios may increase. Alternatively or in addition, some examples of process 400 may include determining changes in vehicle parameters 114 according to one or more statistical methods. For example, system 100 may simulate a fixed number of scenarios of the autonomous vehicle system automatically braking while traveling down an incline, and may randomly determine the weight of the autonomous vehicle system in each scenario according to a normal or Gaussian distribution of the vehicle's weight (i.e., the vehicle parameters) that is centered at 3,000 pounds. More generally, system 100 may use one or more of machine learning, deep learning and/or neural networks to change vehicle parameters 114 at step 412. For example, one or more machine learning algorithms may be used to determine what change in vehicle parameters is most likely to increase performance metrics or improve vehicle parameters in fewest iterations of process 400. Alternatively or in addition, many examples of process 400 may include machine learning, deep learning, and/or neural networks to change vehicle parameters (i.e., control the configuration of the autonomous vehicle system of the scenarios simulated during process 400).

At 414, process 400 is completed and ends in response to determining to forgo additional scenarios of the autonomous vehicle with different vehicle parameters. In some examples, system 100 may record any scenario parameters 110, performance metrics 112, vehicle parameters 114 and/or minimum performance scenarios 116, and any other relevant data, in storage 104 before process 400 is terminated.

FIG. 4B illustrates an example graph 420 with vehicle parameters 114 mapped to performance metrics 112 based on a vehicle analysis, or process 400, according to examples of the disclosure. As described above with reference to FIG. 1, vehicle parameters 114 may vary between consecutive scenarios of the autonomous vehicle system during process 400, such that simulating several scenarios of the autonomous vehicle system with a variety of vehicle parameters 114 may result in a corresponding variety of performance metrics 112 of those scenarios. Moreover and as also described with reference to FIG. 1, system 100 may determine performance metrics 112 for each of the scenarios simulated during process 400, so that for each scenario simulated during process 400 the scenario parameters 110 are identical (e.g., describing a single minimum performance scenario), the vehicle parameters 114 differ between any two scenarios and performance metrics 112 are determined for each scenario, where the performance metrics 112 of each scenario correspond to the vehicle parameters 114 of that scenario. In some examples, therefore, performance metrics 112 of the scenarios simulated during process 400 may be mapped as a function of the vehicle parameters of the corresponding scenario, where the scenario parameters 100 of each scenario are identical.

Point 422 of graph 420 illustrates a performance metric corresponding to vehicle parameters used in the first scenario simulated during process 400. In some examples, the vehicle parameters of point 422 may be described as initial vehicle parameters, and may be the same vehicle parameters used in the scenarios of process 300 to determine the minimum performance scenario (or the scenario parameters 110 of the minimum performance scenario) simulated during process 400. Point 424 of graph 420 is an example of improved vehicle parameters (or an improved vehicle configuration) associated with increased performance metric or a performance above a specified threshold.

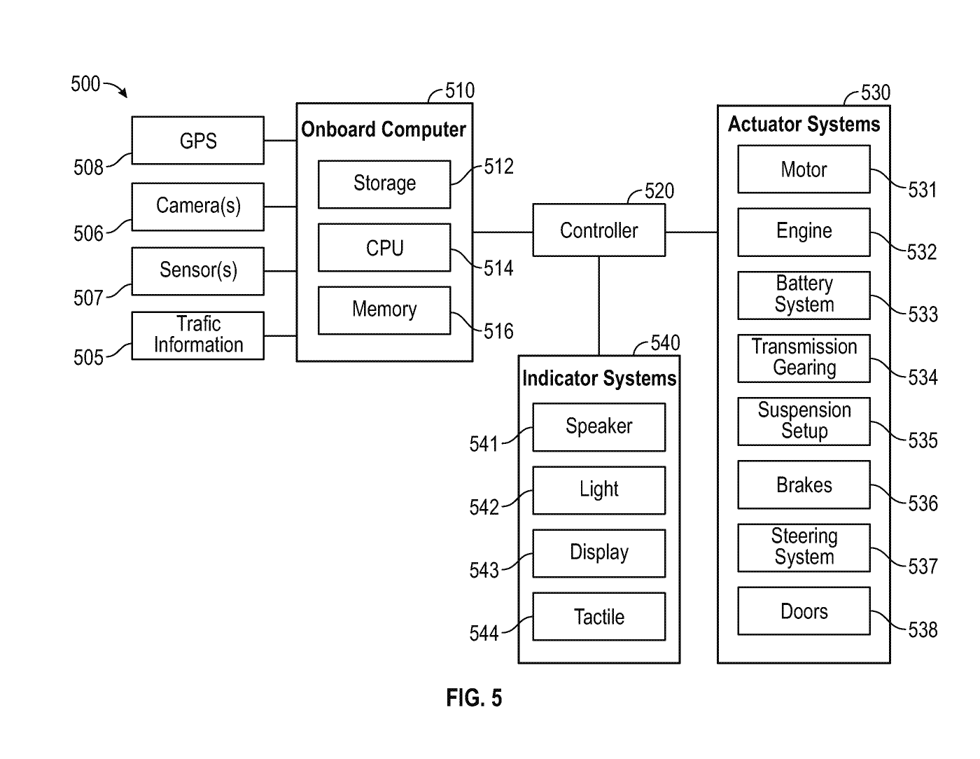

FIG. 5 illustrates an exemplary system block diagram of an autonomous vehicle system including automated driving software according to examples of the disclosure. Vehicle control system 500 can perform automated driving and driving assistance. In some examples, system 500 may be configured to export and/or extract one or more data streams to use as scenario parameters (or vehicle configurations). For example, system 500 may collect data based on sensor data collected and utilized by system 500 to control a vehicle. In some examples, data collected by system 500 may be used to implement any of the algorithms or processes described herein. For example, system 500 may collect data to be used in a scenario analysis (e.g., process 300) as described with reference to FIG. 3A, and may collect data to use in a vehicle analysis (e.g., process 400) as described with reference to FIG. 4A. In certain examples, system 500 may collect data indicative of minimum performance scenarios, based on vehicle configurations that system 500 observes to result in vehicle performance below a certain threshold. Additionally, an example system 500 may be configured to adapt data from one or more vehicle sensors for use in scenarios as scenario parameters, performance metrics, vehicle parameters, and the like.

System 500 can be incorporated into a vehicle, such as a consumer automobile. Other example vehicles that may incorporate the system 500 include, without limitation, airplanes, boats, motorcycles or industrial automobiles. Vehicle control system 500 can include one or more cameras 506 capable of capturing image data (e.g., video data) for determining various characteristics of the vehicle's surroundings. Vehicle control system 500 can also include one or more other sensors 507 (e.g., radar, ultrasonic, LIDAR, etc.) capable of detecting various characteristics of the vehicle's surroundings (e.g., to use as scenario parameters of a scenario). For example, sensors 507 can be used for detecting the presence of an object and a distance between the object and the vehicle. Global Positioning System (GPS) receiver 508 capable of determining the location of the vehicle. In some examples, traffic information 505 can be received (e.g., by an antenna) or accessed (e.g., from storage 512 or memory 516), and can be used for determining automated driving routes.

Vehicle control system 500 can include an on-board computer 510 coupled to the traffic information 505, cameras 506, sensors 507, and GPS receiver 508. On-board computer 510 can be capable of receiving one or more of the traffic information, image data from the cameras, outputs from the sensors 507 and the GPS receiver 508. On-board computer 510 can include storage 512, memory 516, and a processor (central processing unit (CPU)) 514. CPU 514 can execute automated driving software stored in storage 512 and/or memory 514. For example, CPU 514 can process the traffic information, image data, sensor outputs and GPS outputs and make driving decisions thereon. For example, processing can include detecting and tracking objects in the environment, tracking vehicle parameters (e.g., odometer, location), navigation planning, lane selection/change planning, motion planning, determining automated driving commands, etc. Additionally, storage 512 and/or memory 516 can store data and instructions for performing the above processing. Storage 512 and/or memory 516 can be any non-transitory computer readable storage medium, such as a solid-state drive, a hard disk drive or a random access memory (RAM) among other possibilities.

The vehicle control system 500 can also include a controller 520 capable of controlling one or more aspects of vehicle operation based on automated driving commands received from the processor. In some examples, the vehicle control system 500 can be connected to (e.g., via controller 520) one or more actuator systems 530 in the vehicle and one or more indicator systems 540 in the vehicle. The one or more actuator systems 530 can include, but are not limited to, a motor 531 or engine 532, battery system 533, transmission gearing 534, suspension setup 535, brakes 536, steering system 537, and door system 538. The vehicle control system 500 can control, via controller 520, one or more of these actuator systems 530 during vehicle operation; for example, to open or close one or more of the doors of the vehicle using the door actuator system 538, to control the vehicle during autonomous driving or parking operations using the motor 531 or engine 532, battery system 533, transmission gearing 534, suspension setup 535, brakes 536 and/or steering system 537, etc. The one or more indicator systems 540 can include, but are not limited to, one or more lights 542 in the vehicle, one or more tactile actuators 544 in the vehicle (e.g., as part of a steering wheel or seat in the vehicle), and/or one or more infotainment systems 545 (e.g., providing entertainment and/or information to the user). The vehicle control system 500 can control, via controller 520, one or more of these indicator systems 540 to provide indications to a user of the vehicle.

Therefore, according to the above, some examples of the disclosure are directed to a system comprising: one or more processors; and a memory including instructions, which when executed by the one or more processors, cause the one or more processors to perform a method comprising: determining one or more scenario parameters; determining one or more performance metrics; determining a vehicle configuration associated with an autonomously operating vehicle; simulating the autonomously operating vehicle in each of one or more scenarios for each of the one or more scenario parameters, each scenario including the determined one or more scenario parameters, wherein at least one of the one or more scenario parameters for each scenario is different from scenario parameters simulated in other scenarios; and for each simulated scenario, determining the one or more performance metrics associated with the simulated scenario. Additionally or alternatively to one or more of the examples disclosed above, in some examples, the vehicle configuration is same for all of the one or more scenarios. Additionally or alternatively to one or more of the examples disclosed above, in some examples, the method further comprising: storing the one or more performance metrics in the memory. Additionally or alternatively to one or more of the examples disclosed above, in some examples, the one or more scenario parameters include one or more of a distance between the simulated vehicle and an object in a lane, a number of objects in the lane, a location of the object in the lane, one or more weather conditions, and one or more traffic conditions. Additionally or alternatively to one or more of the examples disclosed above, in some examples, the system further comprising: an input component configured to receive the one or more scenario parameters from user input. Additionally or alternatively to one or more of the examples disclosed above, in some examples, determining the one or more scenario parameters includes retrieving one or more scenario parameters from past simulations stored in the memory. Additionally or alternatively to one or more of the examples disclosed above, in some examples, the one or more performance metrics include one or more of a minimum braking distance, maximum range for sensing objects, minimum reaction time, maximum distance between the vehicle and a designated position within a lane, and acceleration of the vehicle. Additionally or alternatively to one or more of the examples disclosed above, in some examples, the method further comprises: mapping the one or more determined performance metrics to the one or more scenario parameters; and determining one or more local minima of the one or more determined performance metrics. Additionally or alternatively to one or more of the examples disclosed above, in some examples, the method further comprises: for each of the one or more local minima, optimizing the vehicle configuration. Additionally or alternatively to one or more of the examples disclosed above, in some examples, the method further comprises: associating the determined one or more local minima to one or more minimum performance scenarios. Additionally or alternatively to one or more of the examples disclosed above, in some examples, the system further comprising: an output component configured to send the one or more minimum performance scenarios to an external database. Additionally or alternatively to one or more of the examples disclosed above, in some examples, simulating the autonomously operating vehicle in the one or more scenarios includes one scenario parameter that incrementally varies.

Some examples of the disclosure are directed to an autonomously operating vehicle comprising: one or more processors; and a memory including instructions, which when executed by the one or more processors, cause the one or more processors to perform a method comprising: determining one or more scenario parameters; determining one or more performance metrics; determining a vehicle configuration associated with the vehicle; simulating the vehicle in each of one or more scenarios for each of the one or more scenario parameters, each scenario including the determined one or more scenario parameters, wherein at least one of the one or more scenario parameters for each scenario is different from scenario parameters simulated in other scenarios; and for each simulated scenario, determining the one or more performance metrics associated with the simulated scenario.

Some examples of the disclosure are directed to a method comprising: determining one or more scenario parameters; determining one or more performance metrics; determining a vehicle configuration associated with an autonomously operating vehicle; simulating the autonomously operating vehicle in each of one or more scenarios for each of the one or more scenario parameters, each scenario including the determined one or more scenario parameters, wherein at least one of the one or more scenario parameters for each scenario is different from scenario parameters simulated in other scenarios; and for each simulated scenario, determining the one or more performance metrics associated with the simulated scenario.

Although examples of this disclosure have been fully described with reference to the accompanying drawings, it is to be noted that various changes and modifications will become apparent to those skilled in the art. Such changes and modifications are to be understood as being included within the scope of examples of this disclosure as defined by the appended claims.

1. A system comprising:
one or more processors; and
a memory including instructions, which when executed by the one or more processors, cause the one or more processors to perform a method comprising:
determining one or more scenario parameters;
determining one or more performance metrics;
determining a vehicle configuration associated with an autonomously operating vehicle;
simulating the autonomously operating vehicle in each of one or more scenarios for each of the one or more scenario parameters, each scenario including the determined one or more scenario parameters,
wherein at least one of the one or more scenario parameters for each scenario is different from scenario parameters simulated in other scenarios; and
for each simulated scenario, determining the one or more performance metrics associated with the simulated scenario.

2. The system of claim 1, wherein the vehicle configuration is same for all of the one or more scenarios.

3. The system of claim 1, wherein the method further comprising:
storing the one or more performance metrics in the memory.

4. The system of claim 1, wherein the one or more scenario parameters include one or more of a distance between the simulated vehicle and an object in a lane, a number of objects in the lane, a location of the object in the lane, one or more weather conditions, and one or more traffic conditions.

5. The system of claim 1, further comprising:
an input component configured to receive the one or more scenario parameters from user input.

6. The system of claim 1, wherein determining the one or more scenario parameters includes retrieving one or more scenario parameters from past simulations stored in the memory.

7. The system of claim 1, wherein the one or more performance metrics include one or more of a minimum braking distance, maximum range for sensing objects, minimum reaction time, maximum distance between the vehicle and a designated position within a lane, and acceleration of the vehicle.

8. The system of claim 1, wherein the method further comprises:
mapping the one or more determined performance metrics to the one or more scenario parameters; and
determining one or more local minima of the one or more determined performance metrics.

9. The system of claim 8, wherein the method further comprises:
for each of the one or more local minima, optimizing the vehicle configuration.

10. The system of claim 8, wherein the method further comprises:
associating the determined one or more local minima to one or more minimum performance scenarios.

11. The system of claim 10, further comprising:
an output component configured to send the one or more minimum performance scenarios to an external database.

12. The system of claim 1, wherein simulating the autonomously operating vehicle in the one or more scenarios includes one scenario parameter that incrementally varies.

13. An autonomously operating vehicle comprising:
one or more processors; and
a memory including instructions, which when executed by the one or more processors, cause the one or more processors to perform a method comprising:
determining one or more scenario parameters;
determining one or more performance metrics;
determining a vehicle configuration associated with the vehicle;
simulating the vehicle in each of one or more scenarios for each of the one or more scenario parameters, each scenario including the determined one or more scenario parameters,
wherein at least one of the one or more scenario parameters for each scenario is different from scenario parameters simulated in other scenarios; and
for each simulated scenario, determining the one or more performance metrics associated with the simulated scenario.

14. A method comprising:
determining one or more scenario parameters;
determining one or more performance metrics;
determining a vehicle configuration associated with an autonomously operating vehicle;
simulating the autonomously operating vehicle in each of one or more scenarios for each of the one or more scenario parameters, each scenario including the determined one or more scenario parameters,
wherein at least one of the one or more scenario parameters for each scenario is different from scenario parameters simulated in other scenarios; and
for each simulated scenario, determining the one or more performance metrics associated with the simulated scenario.
